(19) United States
(12) Patent Application Publication
(10) Pub. No.: US 2021/0193909 A1
(43) Pub. Date: Jun. 24, 2021

(54) METHOD OF MANUFACTURING ULTRASONIC SENSORS

(71) Applicant: BTBL CO., LTD, Seongnam-si, Gyeonggi-do (KR)

(72) Inventors: Young Kyu KIM, Ansan-si, Gyeonggi-do (KR); Kyung Ok PARK, Seoul (KR); Seung Jin LEE, Yongin-si, Gyeonggi-do (KR)

(73) Assignee: BTBL CO., LTD, Seongnam-si, Gyeonggi-do (KR)

(21) Appl. No.: 17/270,425

(22) PCT Filed: Jan. 22, 2019
(86) PCT No.: PCT/KR2019/000931

§ 371 Date: Feb. 22, 2021

(30) Foreign Application Priority Data
Aug. 24, 2018 (KR) 10-2018-0099287

(51) Int. Cl. H01L 41/43; H01L 41/09; H01L 41/047; H01L 41/332

(52) U.S. Cl. CPC H01L 41/43; H01L 41/332; H01L 41/0477; H01L 41/09

(57) ABSTRACT

Disclosed is a method of manufacturing ultrasonic sensors. The method includes forming a micropattern having concave and convex portions on an etchable substrate, filling a piezoelectric material in the concave portions of the micropattern, pressurizing the filled piezoelectric material, sintering the piezoelectric material to form preliminary piezoelectric bodies, re-sintering the preliminary piezoelectric bodies to form densely packed unit piezoelectric bodies, and forming electrode terminals at both ends of each of the unit piezoelectric bodies to produce a unit piezoelectric cell. The method enables the manufacture of high-quality ultrasonic sensors in high yield.

### TECHNICAL FIELD

The present invention relates to a method of manufacturing ultrasonic sensors, and more specifically to a method of manufacturing high-quality ultrasonic sensors in high yield.

### BACKGROUND ART

In an ultrasonic sensor array, an ultrasonic transmitter may be used to send an ultrasonic wave through an ultrasonically transmissive medium or media and towards an object to be detected. The transmitter may be operatively coupled with an ultrasonic sensor configured to detect portions of the ultrasonic wave that are reflected from the object. For example, in ultrasonic fingerprint imagers, an ultrasonic pulse may be produced by starting and stopping the transmitter during a very short interval of time. At each material interface encountered by the ultrasonic pulse, a portion of the ultrasonic pulse is reflected.

For example, in the context of an ultrasonic fingerprint imager, the ultrasonic wave may travel through a platen on which a person's finger may be placed to obtain a fingerprint image. After passing through the platen, some portions of the ultrasonic wave encounter skin that is contact with the platen, e. g., the fingerprint ridges, while other portions of the ultrasonic wave encounter air, e. g., valleys between adjacent ridges of a fingerprint, and may be reflected with different intensities back towards the ultrasonic sensor. The reflected signals associated with the finger may be processed and converted to a digital value representing the signal strength of the reflected signal.

When multiple such reflected signals are collected over a distributed area, the digital values of such signals may be used to produce a graphical display of the signal strength over the distributed area, for example by converting the digital values to an image, thereby producing an image of the fingerprint. Thus, an ultrasonic sensor may be used as a fingerprint sensor or other type of biometric sensor.

That is, an ultrasonic sensor is a device that transmits an ultrasonic wave towards an object and receives signals from the object to detect the object. The object reflects the ultrasonic wave, produces the signals, and returns the signals to the ultrasonic sensor. Such an ultrasonic sensor essentially consists of an ultrasonic wave transmitting/receiving unit, a driving unit, and other accessories. The ultrasonic wave transmitting/receiving unit receives an alternating current voltage from the driving unit, transmits an ultrasonic wave, receives signals from an object in response to the transmitted ultrasonic wave, and transmits the signals to the driving unit. The ultrasonic wave transmitting/receiving unit essentially includes a case and a piezoelectric element. When an alternating current passes through the piezoelectric element, the piezoelectric crystals undergo repeated expansion and contraction to produce mechanical vibration, which is called “converse piezoelectric effect”. For example, when repeated expansion and contraction occurs by an external force applied to the piezoelectric element, positive (+) charges are created at one side of the piezoelectric element and negative (−) charges are created at the other side to generate an electric current. An externally applied alternating current applied to the piezoelectric element causes repeated expansion and contraction of the piezoelectric element to produce mechanical vibration, which is transmitted to the case. The vibration of the case generates a compressional wave in air to transmit an ultrasonic wave. The ultrasonic sensor repeats this ultrasonic wave transmission process.

On the other hand, when the ultrasonic sensor receives an ultrasonic wave, a compressional wave in air is transmitted to a diaphragm of the case to displace the case. Due to this displacement, the piezoelectric element expands and contracts to generate an alternating current.

Korean Patent No. 1850127 discloses a method of manufacturing ultrasonic sensors, including: sintering a piezoelectric sheet under incomplete sintering conditions to prepare a ceramic sintered body; cutting the ceramic sintered body at predetermined intervals from a first surface in parallel to a first direction to such depths that some areas remain on a second surface and cutting the ceramic sintered body at predetermined intervals from the second surface in parallel to a second direction perpendicular to the first direction to such depths that some areas remain on the first surface, to prepare a ceramic processed body; sintering the ceramic processed body under predetermined complete sintering conditions; cutting the ceramic processed body to form recesses and filling an insulating material in the recesses; and arranging arrays of piezoelectric rods on the first and second surfaces and polishing the piezoelectric rods such that the areas remaining on the first and second surfaces are removed and the piezoelectric rods are exposed. However, the cutting of the piezoelectric rods requires much time, resulting in low yield of ultrasonic sensors, and may deteriorate the quality of the piezoelectric rods.

### DISCLOSURE OF INVENTION

### Technical Problem

Therefore, an object of the present invention is to provide a method of manufacturing high-quality ultrasonic sensors in high yield.

### Solution to Problem

One aspect of the present invention provides a method of manufacturing ultrasonic sensors, including forming a micropattern having concave and convex portions on an etchable substrate, filling a piezoelectric material in the concave portions of the micropattern, pressurizing the filled piezoelectric material, sintering the piezoelectric material to form preliminary piezoelectric bodies, re-sintering the preliminary piezoelectric bodies to form densely packed unit piezoelectric bodies, and forming electrode terminals at both ends of each of the unit piezoelectric bodies to produce a unit piezoelectric cell.

According to one embodiment of the present invention, a powder of the piezoelectric material may be filled by spraying.

According to a further embodiment of the present invention, the piezoelectric material powder may have an average particle size of 0.1 to 10 μm.

According to a further embodiment of the present invention, the pressurization may be performed at a pressure of 200 to 700 MPa.

According to a further embodiment of the present invention, the sintering may be performed at a temperature where the surface of the piezoelectric material is melted.

According to a further embodiment of the present invention, the re-sintering may be performed at a temperature where the surfaces of the preliminary piezoelectric bodies are melted.

According to a further embodiment of the present invention, a paste or solution prepared by mixing a powder of the piezoelectric material with a solvent and a binder may be filled.

According to a further embodiment of the present invention, the etchable substrate may be electrically conductive.

According to a further embodiment of the present invention, some of the convex portions of the etchable substrate may be lead electrodes.

### Advantageous Effects of Invention

The method of the present invention enables the manufacture of high-quality ultrasonic sensors in high yield.

### BRIEF DESCRIPTION OF DRAWINGS

FIG. 1 illustrates ultrasonic sensors manufactured on an etchable substrate by a method of the present invention.

FIG. 2 is a cross-sectional view illustrating concave portions and convex portions of a micropattern formed on a substrate.

FIG. 3 is a cross-sectional view illustrating a process for filling a piezoelectric material in concave portions of a micropattern and pressurizing the piezoelectric material.

FIG. 4 conceptually illustrates the shape of particles of a preliminary piezoelectric body after sintering in accordance with a method of the present invention.

FIG. 5 conceptually illustrates the shape of particles of a unit piezoelectric body after re-sintering in accordance with a method of the present invention.

FIG. 6 cross-sectionally illustrates a process for etching some convex portions on a substrate using a photoresist formed on unit piezoelectric bodies after re-sintering to form electrodes and stacking an insulating material on the substrate in accordance with a method of the present invention.

FIG. 7 exemplarily illustrates a process for molding electrode terminals on unit piezoelectric bodies and cross-sectionally illustrates a concept in which a first electrode terminal E1 is stacked and etched according to a designed pattern and a second electrode terminal E2 is stacked and etched according to the pattern.

FIG. 8 is a cross-sectional scanning electron microscopy image of ultrasonic sensors manufactured in Example 1.

FIG. 9 is a scanning electron microscopy image of a preliminary piezoelectric body after sintering, which was formed in Comparative Example 1.

FIG. 10 is a scanning electron microscopy image of a unit piezoelectric body after re-sintering, which was formed in Example 1.

FIG. 11 is a scanning electron microscopy image of a unit piezoelectric body after re-sintering, which was formed in Example 2.

FIG. 12 shows the impedance values of an ultrasonic sensor manufactured in Comparative Example 1.

FIG. 13 shows the impedance values of an ultrasonic sensor manufactured in Example 2.

### MODE FOR THE INVENTION

The present invention will now be described in detail with reference to the accompanying drawings.

Technical terms used in this specification are used to merely illustrate specific embodiments, and should be understood that they are not intended to limit the present invention.

As far as not being defined differently, all terms used herein including technical or scientific terms may have the same meaning as those generally understood by an ordinary person skilled in the art to which the present invention belongs to, and should not be construed in an excessively comprehensive meaning or an excessively restricted meaning. In addition, if a technical term used in the description of the present invention is an erroneous term that fails to clearly express the idea of the present invention, it should be replaced by a technical term that can be properly understood by the skilled person in the art. In addition, general terms used in the description of the present invention should be construed according to definitions in dictionaries or according to its front or rear context, and should not be construed to have an excessively restrained meaning. A singular representation may include a plural representation as far as it represents a definitely different meaning from the context. Terms “include” or “has” used herein should be understood that they are intended to indicate an existence of several components or several steps, disclosed in the specification, and it may also be understood that part of the components or steps may not be included or additional components or steps may further be included. In the description of the present invention, detailed explanations of related art are omitted when it is deemed that they may unnecessarily obscure the essence of the present invention.

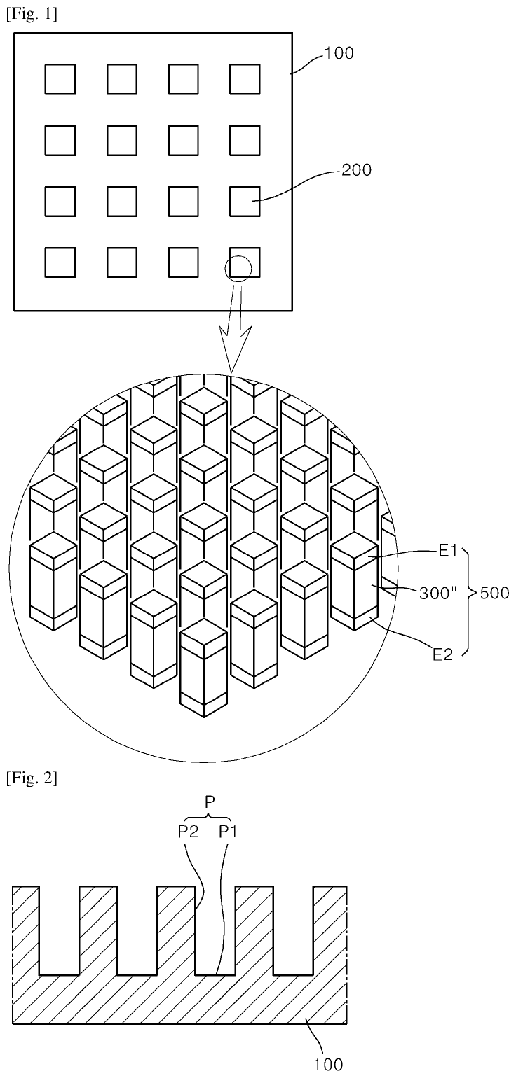

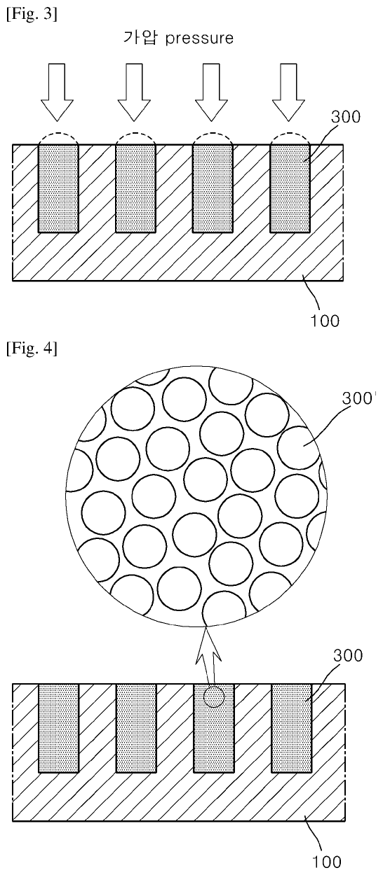

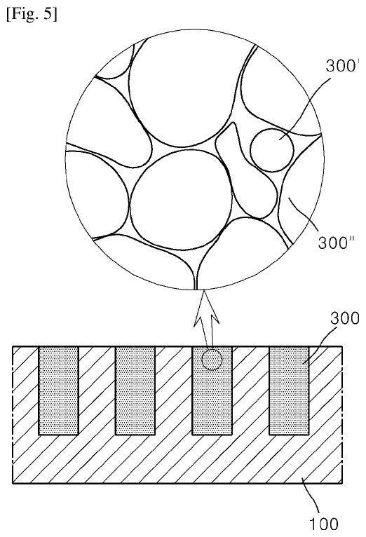

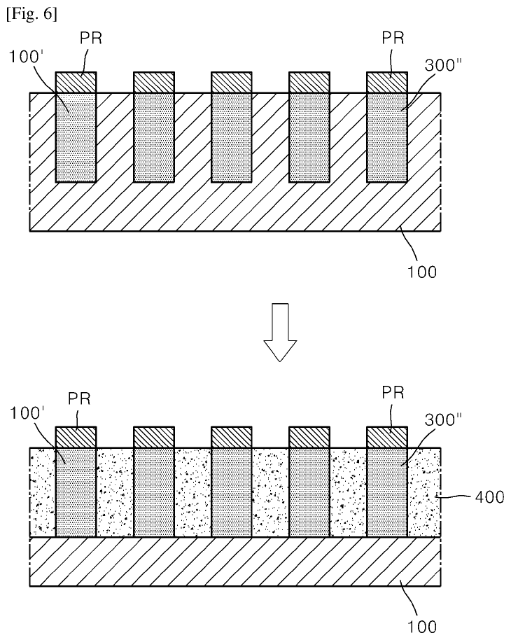

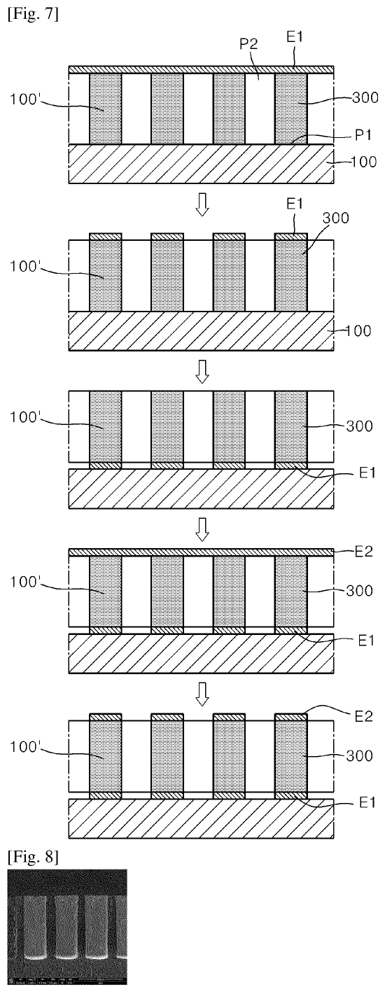

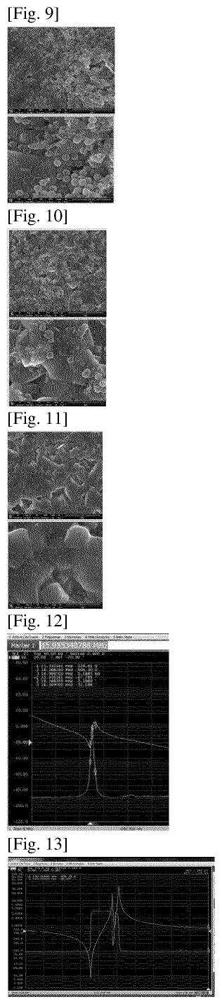

FIG. 1 illustrates ultrasonic sensors manufactured on an etchable substrate by a method of the present invention, FIG. 2 is a cross-sectional view illustrating concave portions and convex portions of a micropattern formed on a substrate, FIG. 3 is a cross-sectional view illustrating a process for filling a piezoelectric material in concave portions of a micropattern and pressurizing the piezoelectric material, FIG. 4 conceptually illustrates the shape of particles of a preliminary piezoelectric body after sintering in accordance with a method of the present invention, FIG. 5 conceptually illustrates the shape of particles of a unit piezoelectric body after re-sintering in accordance with a method of the present invention, FIG. 6 cross-sectionally illustrates a process for etching some convex portions on a substrate using a photoresist formed on unit piezoelectric bodies after re-sintering to form electrodes and stacking an insulating material on the substrate in accordance with a method of the present invention, FIG. 7 exemplarily illustrates a process for molding electrode terminals on unit piezoelectric bodies and cross-sectionally illustrates a concept in which a first electrode terminal E1 is stacked and etched according to a designed pattern and a second electrode terminal E2 is stacked and etched according to the pattern, FIG. 8 is a cross-sectional scanning electron microscopy image of ultrasonic sensors manufactured in Example 1, FIG. 9 is a scanning electron microscopy image of a preliminary piezoelectric body after sintering, which was formed in Comparative Example 1, FIG. 10 is a scanning electron microscopy image of a unit piezoelectric body after re-sintering, which was formed in Example 1, FIG. 11 is a scanning electron microscopy image of a unit piezoelectric body after re-sintering, which was formed in Example 2, FIG. 12 shows the impedance values of an ultrasonic sensor manufactured in Comparative Example 1, and FIG. 13 shows the impedance values of an ultrasonic sensor manufactured in Example 2.

A method of manufacturing ultrasonic sensors according to the present invention includes forming a micropattern having concave and convex portions on an etchable substrate (S1), filling a piezoelectric material in the concave portions of the micropattern (S2), pressurizing the filled piezoelectric material (S3), sintering the piezoelectric material to form preliminary piezoelectric bodies (S4), re-sintering the preliminary piezoelectric bodies to form densely packed unit piezoelectric bodies (S5), and forming electrode terminals at both ends of each of the unit piezoelectric bodies to produce a unit piezoelectric cell (S6).

First, in S1, a micropattern P having concave and convex portions is formed on an etchable substrate 100. According to the method of the present invention, the manufacture of ultrasonic sensors 200 is not based on cutting, which encounters the problems mentioned in the Background Art, but starts from the formation of the micropattern P on the etchable substrate 100.

Any material that can be formed into a micropattern by wet or dry etching may be used without particular limitation for the etchable substrate 100. Preferably, the etchable substrate 100 is made of a material that does not undergo a change in physical properties or flatness, such as distortion, by thermal energy applied in the subsequent sintering or re-sintering.

Examples of such etchable substrates include silicon wafers, glass wafers, and ceramic substrates.

The etchable substrate has the ability to carry an electric current. Due to this ability, a closed circuit for polarization can be formed even without via-holes or through-holes. The etchable substrate may be a silicon wafer, glass wafer or ceramic substrate doped with a controlled concentration of a conductive material, metal ions or an electrically conductive fine powder. This doping can achieve an overall low resistance of the etchable substrate.

As described above, doping can be done to make the glass wafer electrically conductive. Alternatively, indium tin oxide (ITO) or fluorine-doped tin oxide (FTO), and optionally together with titanium oxide (TiO₂), tin oxide (SnO₂), zinc oxide (ZnO), tungsten oxide (WO₃), niobium oxide (Nb₂O₅) or strontium titanate oxide (TiSrO₃), may be deposited on the glass wafer by sputtering to ensure electrical conductivity of the glass wafer. Alternatively, a nano-scale oxide layer may be stacked on a glass wafer to ensure electrical conductivity of the glass wafer.

The resistance is preferably from 0.001 to 0.01 Ωcm. A lower resistance of the etchable substrate indicates better electrical conductivity of the etchable substrate. If the resistance of the etchable substrate exceeds the upper limit defined above, the electrical properties of the ultrasonic sensors deteriorate, resulting in low sensitivity to ultrasonic signals and reduced resolution.

A photolithography process can be employed for precise molding of the micropattern by etching.

Specifically, according to the photolithography process, a photoresist PR is applied to the upper surface of the substrate and cured, and functional light such as UV light is irradiated onto the etchable substrate through a photomask having a pattern corresponding to the micropattern. The light is transmitted only through the pattern of the photomask and only the portions of the photoresist corresponding to the pattern of the photomask are exposed.

Thereafter, the unexposed portions are removed by development, leaving the micropattern on the substrate.

Then, in S2, a piezoelectric material 300 is filled in the concave portions of the micropattern to form unit cell precursors of the ultrasonic sensors.

The concave portions P1 have various shapes and are formed at predetermined intervals according to a design of the micropattern.

The concave portions P1 of the micropattern are recessed portions and are filled with the piezoelectric material 300. The concave portions are operated as unit cells of the ultrasonic sensors.

The piezoelectric material is a ceramic whose shape varies during sintering. Examples of such ceramic materials include barium titanate compounds, PbZrTiO₃ (PZT) compounds, Pb(Sc,Ta)O₃ (PST) compounds, (Pb,Sm)TiO₃ compounds, and Pb(MgNb)O₃-PT(PbTiO₃) (PMN) compounds.

Here, the density of the piezoelectric material powder is an important factor in filling the piezoelectric material 300. Thus, the average particle size of the piezoelectric material powder is adjusted to 0.1 to 10 μm for spraying.

A paste or solution prepared by mixing a powder of the piezoelectric material with a solvent and a binder may be filled.

Since the solvent and the binder are organic materials, they are easily removed by evaporation or oxidation during heating for drying or curing, assisting in filling the piezoelectric material powder.

The kinds of the solvent and the binder are not particularly limited so long as high concentrations of the solvent and the binder can be homogeneously mixed with the piezoelectric material powder.

A crystallization agent may be further added to grow the filled particles upon subsequent pressurization and sintering, with the result that the grain size increases.

As the crystallization agent, there may be used, for example, an ionic liquid of a pyrazine, imidazolium, benzimidazolium or pyrrolidinium halide in a solvent, such as isopropyl alcohol, methanol, ethanol, propanol, butanol, pentanol, diacetone alcohol, phenol, acetone, acetonitrile, methyl cellosolve, ethyl cellosolve or butyl cellosolve. The crystallization agent may be a compound having an alkyl/allyl chain with cyano (CN) groups at both ends or two pyridine groups.

Next, in S3, the filled piezoelectric material is pressurized.

Pores exist between the particles of the piezoelectric material. The number of the pores is not substantially reduced even after subsequent sintering or re-sintering, eventually adversely affecting the electrical and physical properties of the piezoelectric material.

The pressurization is performed to minimize the number of the pores. For this purpose, gas pressurization or pressing is used. The gas pressurization is preferably performed at a pressure of 200 to 700 MPa.

If the pressure is less than 200 MPa, the effect of reducing the number of the pores is negligible, with the result that the electrical and physical properties of the piezoelectric material are not substantially improved. Meanwhile, if the pressure exceeds 700 MPa, the number of the pores is minimized to some extent but high maintenance and repair costs are incurred, adversely affecting the manufacture of the ultrasonic sensors.

Vibration may be applied to the piezoelectric material during the pressurization. The vibration of the piezoelectric material displaces the piezoelectric material powder, which is helpful in removing the pores. A frequency correlating with the size of the piezoelectric material powder is used to vibrate the piezoelectric material. The frequency is preferably from 1 to 600 kHz. If the frequency is less than 1 kHz, there is no significant influence on the displacement of the particles. Meanwhile, if the frequency exceeds 600 kHz, the excessive energy is uneconomical because a significant influence on the displacement of the piezoelectric material particles is not exhibited.

Next, in S4, the piezoelectric material 300 is sintered to form preliminary piezoelectric bodies 300′.

After the number of the pores in the piezoelectric material is minimized by the pressurization, sintering is performed to form current-carrying paths between the particles. This sintering does not require excessive thermal energy to change the phase of the particles to a liquid but requires heat at a temperature where the surface of the piezoelectric material is melted. The temperature of the heat is not limited so long as current-carrying paths are formed.

Next, in S5, the preliminary piezoelectric bodies 300′ are re-sintered to form densely packed unit piezoelectric bodies 300″.

The re-sintering is performed at a temperature where the surfaces of the preliminary piezoelectric bodies are melted. Specifically, in S5, thermal energy is applied in an amount to melt only the surfaces of the preliminary piezoelectric bodies without changing the phase of the particles of the preliminary piezoelectric bodies to a liquid phase. The volume of the particles of the preliminary piezoelectric bodies increases after coagulation.

Next, in S6, electrode terminals E1 and E2 are formed at both ends of each of the unit piezoelectric bodies 300″ to produce a unit piezoelectric cell 500.

An external circuit or module is connected to the electrode terminals formed at the ends of the re-sintered unit piezoelectric bodies 300″ to drive the ultrasonic sensors 200.

Any material that is highly electrically conductive and has low resistance may be used without limitation for the electrode terminals E1 and E2. An electrically conductive metal such as silver, copper or aluminum may be used as a material for the electrode terminals E1 and E2.

The electrode terminals may be stacked by screen printing a paste of the electrically conductive material powder according to a designed pattern of terminal wire electrodes (not illustrated), followed by molding and curing the paste. The paste is prepared by mixing the electrically conductive material powder with a binder.

The substrate 100 can be removed by a photolithography process. An insulating dielectric material 400 may be filled in a space between the unit piezoelectric bodies to minimize interference between the unit piezoelectric bodies when a voltage is applied and an ultrasonic wave is transmitted and received. The insulating material is preferably a polymer resin.

The electrode terminals E1 and E2 are essentially arranged opposite to each other. For use in the ultrasonic sensors, the electrode terminals need to be connected to each other. For this purpose, wires or through-holes or via-holes may be used. However, this connection process is troublesome and difficult to carry out. In the present invention, the etchable substrate 100 is used per se to arrange the terminal wires in one direction.

Thus, the etchable substrate should be electrically conductive. That is, any low resistance material may be used for the etchable substrate. Some of the convex portions of the etchable substrate may be arranged as lead electrodes 100′. For this arrangement, the photoresist PR is disposed on a pattern of the lead electrodes before etching.

In conclusion, when an electric current is allowed to flow from an external circuit or module, a corresponding voltage is applied to the unit piezoelectric bodies 300″ through the wire electrodes and the lead electrodes to cause expansion and contraction or vibration of the unit piezoelectric bodies and to generate an ultrasonic wave with a particular frequency. The ultrasonic wave is scanned (transmitted: Tx) in a specific direction, for example, to a person's finger. Each of the ultrasonic sensors reads reflected frequencies (received: Rx) and compares them with the registered person's fingerprint information to determine the identity of the fingerprint.

The unit piezoelectric bodies 500 are combined into each of the ultrasonic sensors 200. For example, hundreds to thousands of unit piezoelectric cells are arranged in an area of several to several tens of mm² corresponding to the size of a fingertip. The number of the unit piezoelectric cells can be determined depending on the accuracy and precision of fingerprint authentication.

The ultrasonic sensors 200 may be manufactured by a cutting process such as dicing.

### Example 1

A micropattern with a line width of 50 μm was formed on a silicon wafer by a photolithography process. A PZT piezoelectric powder (average particle size=0.5-3 μm) was filled in concave portions of the micropattern by spraying, pressurized at 300 MPa, heated at 1° C./min, maintained at 850° C. for 2 h, and cooled at 1° C./min. The sintering and cooling procedure was repeated under the same conditions. The substrate was removed by a photolithography process, an epoxy insulating material was filled, gold metal was deposited, wire electrodes were patterned by a photolithography process, and diced into ultrasonic sensors.

### Example 2

Ultrasonic sensors were manufactured in the same manner as in Example 1, except that the pressurization was performed at 400 MPa.

### Comparative Example 1

Ultrasonic sensors were manufactured in the same manner as in Example 1, except that the pressurization was performed at 30 MPa and the re-sintering was omitted.

### Experimental Example 1

The ultrasonic sensors of Comparative Example 1 and Examples 1-2 were imaged using a scanning electron microscope (SEM). The images are shown in FIGS. 8-11. Referring to FIG. 9, a larger number of pores were formed between the particles with a smaller particle size in the ultrasonic sensor of Comparative Example 1. In contrast, smaller numbers of pores were formed between the particles with larger particle sizes in the ultrasonic sensors of Examples 1-2 (see FIGS. 10 and 11).

### Experimental Example 2

The impedance values of the ultrasonic sensors manufactured in Comparative Example 1 and Example 2 were measured when ultrasonic waves were transmitted from and received by the ultrasonic sensors and are shown in FIGS. 12 and 13, respectively. For the ultrasonic sensor of Comparative Example 1, the impedance peaks of the transmission and reception lines were difficult to discern (see FIG. 12). In contrast, the impedance peaks of the ultrasonic sensor of Example 2 were clear. These results demonstrate that the ultrasonic sensor of Example 2 has higher quality than the ultrasonic sensor of Comparative Example 1.

### LIST OF REFERENCE NUMERALS

100: Etchable substrate 200: Ultrasonic sensors
300: Piezoelectric material 300′: Preliminary piezoelectric bodies
300″: Unit piezoelectric bodies 400: Insulating material
500: Unit piezoelectric cells P1/2: Concave/convex portions

1. A method of manufacturing ultrasonic sensors, comprising forming a micropattern having concave and convex portions on an etchable substrate, filling a piezoelectric material in the concave portions of the micropattern, pressurizing the filled piezoelectric material, sintering the piezoelectric material to form preliminary piezoelectric bodies, re-sintering the preliminary piezoelectric bodies to form densely packed unit piezoelectric bodies, and forming electrode terminals at both ends of each of the unit piezoelectric bodies to produce a unit piezoelectric cell.

2. The method according to claim 1, wherein a powder of the piezoelectric material is filled by spraying.

3. The method according to claim 2, wherein the piezoelectric material powder has an average particle size of 0.1 to 10 μm.

4. The method according to claim 1, wherein the pressurization is performed at a pressure of 200 to 700 MPa.

5. The method according to claim 1, wherein the sintering is performed at a temperature where the surface of the piezoelectric material is melted.

6. The method according to claim 1, wherein the re-sintering is performed at a temperature where the surfaces of the preliminary piezoelectric bodies are melted.

7. The method according to claim 1, wherein a paste or solution prepared by mixing a powder of the piezoelectric material with a solvent and a binder is filled.

8. The method according to claim 1, wherein the etchable substrate is electrically conductive.

9. The method according to claim 8, wherein some of the convex portions of the etchable substrate are lead electrodes.
